(19) United States
(12) Patent Application Publication
(10) Pub. No.: US 2026/0106124 A1
(43) Pub. Date: Apr. 16, 2026

(54) CONTROL DEVICE, SUBSTRATE PROCESSING APPARATUS, AND SUBSTRATE PROCESSING METHOD

(71) Applicant: Tokyo Electron Limited, Tokyo (JP)

(72) Inventors: Akira HIRATA, Tokyo (JP); Takahisa MASE, Nirasaki City (JP); Toshiyuki ITO, Nirasaki City (JP); Tatsuya YAMAGUCHI, Tokyo (JP)

(21) Appl. No.: 19/419,501

(22) Filed: Dec. 15, 2025

Related U.S. Application Data
(63) Continuation of application No. PCT/JP2024/021004, filed on Jun. 10, 2024.

(30) Foreign Application Priority Data
Jun. 23, 2023 (JP) 2023-103492

(51) Int. Cl. H01J 37/32; C23C 16/52; G05B 19/418; H10P 74/00

(52) U.S. Cl. CPC H01J 37/3299; C23C 16/52; G05B 19/41875; H01J 37/32724; H10P 74/238; G05B 2219/33034; H01J 2237/332

(57) ABSTRACT

A control device for controlling a state quantity in a substrate processing apparatus performing processing on a substrate, the control device includes: a feedback controller configured to apply a control signal to a control target, based on a deviation between a target value of the state quantity and a detected value from a detector; and a correction value calculator configured to acquire a deviation eⱼ between the target value and the detected value in j-th substrate processing (where j is an integer of 1 or greater) and calculate a correction value to be added to the control signal from the feedback controller during (j+1)-th substrate processing, so that a deviation eⱼ₊₁ between the target value and the detected value in the (j+1)-th substrate processing becomes smaller than the deviation eⱼ.

### CROSS-REFERENCE TO RELATED APPLICATION

The application is a Bypass Continuation application of PCT International Application No. PCT/JP2024/021004, filed on Jun. 10, 2024 and designating the United States, the international application being based upon and claiming the benefit of priority from Japanese Patent Application No. 2023-103492, filed on Jun. 23, 2023, the entire content of which is incorporated herein by reference.

### TECHNICAL FIELD

The present disclosure relates to a control device, a substrate processing apparatus, and a substrate processing method.

### BACKGROUND

In a manufacturing process of a semiconductor device, substrate processing such as film formation and etching is performed within a processing container. In a substrate processing apparatus that performs such substrate processing, it is important to control state quantities such as temperature, pressure, and gas flow rate.

In the substrate processing apparatus, control of state quantities is generally performed using feedback control. For example, Patent Document 1 describes the use of feedback control for controlling temperature in a heat treatment apparatus of a semiconductor device.

### PRIOR ART DOCUMENTS

### Patent Documents

Patent Document 1: Japanese Patent Laid-Open Publication No. 2000-183072

### SUMMARY

According to one embodiment of the present disclosure, there is provided a control device for controlling a state quantity in a substrate processing apparatus performing processing on a substrate, the control device including: a feedback controller configured to apply a control signal to a control target, based on a deviation between a target value of the state quantity and a detected value from a detector; and a correction value calculator configured to acquire a deviation eⱼ between the target value and the detected value in j-th substrate processing (where j is an integer of 1 or greater) and calculate a correction value to be added to the control signal from the feedback controller during (j+1)-th substrate processing, so that a deviation eⱼ₊₁ between the target value and the detected value in the (j+1)-th substrate processing becomes smaller than the deviation eⱼ.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a control block diagram for a general feedback control in the related art.

FIG. 2 is a cross-sectional view illustrating an example of a film formation apparatus as a substrate processing apparatus to which a control device according to one embodiment is applied.

FIG. 3 is a control block diagram illustrating the control device according to the embodiment.

FIG. 4 is a diagram illustrating an example of a control target of the control device according to the embodiment.

FIG. 5 is a control block diagram illustrating a control device in a case in which a correction value calculator is an ILC circuit.

FIG. 6 is a diagram illustrating a circuit configuration of a control circuit used in a method of designing L(jω) from G(jω)S(jω) directly obtained in closed-loop system identification.

FIG. 7 is a diagram illustrating a circuit configuration of a control circuit obtained by equivalently transforming the control circuit of FIG. 6.

FIG. 8 is a diagram illustrating a frequency response obtained by closed-loop system identification.

FIG. 9 is a diagram illustrating L(jω) designed by modeling using fitting based on the frequency response.

FIG. 10 is a diagram illustrating a Q filter designed to guarantee the convergence of a deviation (error) eⱼ in all frequency domains.

FIGS. 11A and 11B are diagrams illustrating stage temperature and control input in a case in which the stage temperature is controlled only by feedback control.

FIGS. 12A and 12B are diagrams illustrating a control waveform (temperature behavior) of an existing stage A and a control waveform (temperature behavior) of a new stage A′ obtained by improving the existing stage A.

FIG. 13 is a diagram illustrating stage temperature, control input, and an ILC signal in a case in which the stage temperature is controlled only by feedback control without using an ILC circuit in Experimental Example 1.

FIG. 14 is a diagram illustrating the stage temperature, the control input, and the ILC signal in a case in which a first ILC experiment is performed in Experimental Example 1.

FIG. 15 is a diagram illustrating the stage temperature, the control input, and the ILC signal in a case in which a second ILC experiment is performed in Experimental Example 1.

FIG. 16 is a diagram illustrating the stage temperature, the control input, and the ILC signal in a case in which a third ILC experiment is performed in Experimental Example 1.

FIG. 17 is a diagram illustrating the stage temperature, the control input, and the ILC signal in a case in which a fourth ILC experiment is performed in Experimental Example 1.

FIG. 18 is a diagram illustrating the stage temperature, the control input, and the ILC signal in a case in which a fifth ILC experiment is performed in Experimental Example 1.

FIG. 19 is a diagram illustrating a relationship between the number of ILC experiments and a root mean squared error (RMSE) representing the fluctuation of the stage temperature in Experimental Example 1.

FIG. 20 is a diagram illustrating stage temperature, control input, and an ILC signal in a case in which the stage temperature is controlled only by feedback control without using an ILC circuit in Experimental Example 2.

FIG. 21 is a diagram illustrating the stage temperature, the control input, and the ILC signal in a case in which a first ILC experiment is performed in Experimental Example 2.

FIG. 22 is a diagram illustrating the stage temperature, the control input, and the ILC signal in a case in which a second ILC experiment is performed in Experimental Example 2.

FIG. 23 is a diagram illustrating the stage temperature, the control input, and the ILC signal in a case in which a third ILC experiment is performed in Experimental Example 2.

FIG. 24 is a diagram illustrating the stage temperature, the control input, and the ILC signal in a case in which a fourth ILC experiment is performed in Experimental Example 2.

FIG. 25 is a diagram illustrating the stage temperature, the control input, and the ILC signal in a case in which a fifth ILC experiment is performed in Experimental Example 2.

FIG. 26 is a diagram illustrating a relationship between the number of ILC experiments and an RMSE representing the fluctuation of the stage temperature in Experimental Example 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments

Hereinafter, an embodiment will be described with reference to the attached drawings.

### Background and Outline

First, background and outline will now be described.

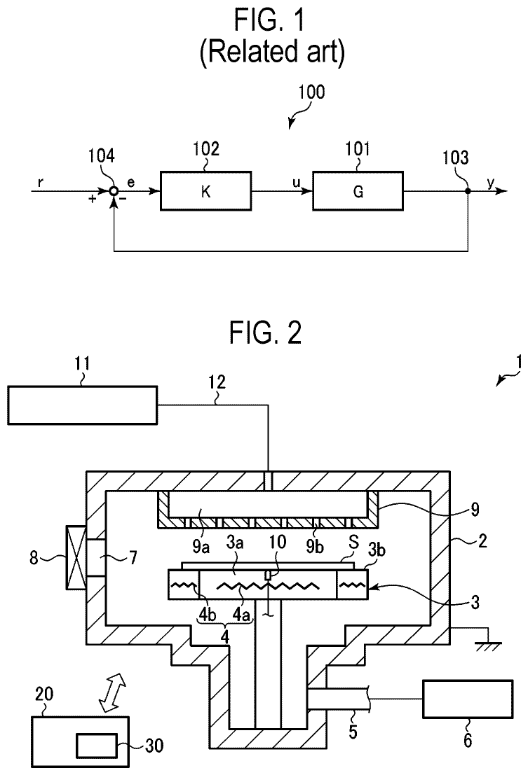

In substrate processing by a substrate processing apparatus, state quantities such as temperature, pressure, and gas flow rate have been controlled by feedback control in the related art. FIG. 1 is a control block diagram for a general feedback control in the related art. As shown in FIG. 1, a control device 100 controls a control target 101 by a feedback controller 102, based on a detected value y which is detected by a detector 103. The feedback controller 102 applies control input u to the control target 101 so that a deviation (error) e, calculated by a subtractor 104, between a target value r and the detected value y from the detector 103 is eliminated.

However, since feedback control controls a state quantity based on an actually detected value, delay occurs during control. Therefore, when the deviation (error) e between the detected value y and the target value r increases due to a disturbance or the like, overshoot and the like occur, resulting in a large fluctuation in the state quantity of the control target. Consequently, it takes time for the state quantity to stabilize at the target value, and a difference between machines is likely to occur, which becomes a factor causing variation in a process result.

In addition, the substrate has various states. For example, when the substrate is a wafer, there are a bare wafer, a patterned wafer, or a wafer with different film thicknesses for formed films. When the state of the substrate differs, a state quantity, for example, a temperature behavior, may change, thereby affecting controllability. As processing is repeatedly performed, a state within a chamber may change due to, for example, film accumulation within the chamber or component consumption within the chamber, thereby affecting controllability. In addition, when substrate transfer and loading conditions of a recipe differ, or between different chambers or different stage heaters, the controllability of state quantities changes. These differences in controllability also affect the process result, and such differences in controllability cannot be handled by feedback control alone.

In addition, there is a demand to adjust a control waveform of a state quantity so that the waveform of a state quantity of a control target matches the waveform of another control target. However, such a demand cannot be satisfied by feedback control alone.

Accordingly, the present embodiment provides a control device for controlling a state quantity in a substrate processing apparatus that performs processing on a substrate. The control device includes a feedback controller that applies a control signal to a control target, based on a deviation between a target value of the state quantity and a detected value from a detector, and a correction value calculator having the following configuration. The correction value calculator acquires a deviation eⱼ between the target value and the detected value in j-th substrate processing (where j is an integer of 1 or greater) and calculates a correction value to be added to the control signal from the feedback controller during (j+1)-th substrate processing, so that a deviation eⱼ₊₁ between the target value and the detected value in the (j+1)-th substrate processing becomes smaller than the deviation eⱼ.

With such a configuration, controllability that cannot be obtained using feedback control in the related art can be realized. That is, according to the present embodiment, since a correction value is calculated so that the deviation in (j+1)-th substrate processing becomes smaller than the deviation in j-th substrate processing, and the correction value is added to a control signal corresponding to the (j+1)-th substrate processing, the deviation converges. Accordingly, by suppressing a fluctuation in the state quantity of the control target due to a disturbance or the like, the state quantity can stabilize at the target value in a short time. Furthermore, the waveform of the state quantity of the control target can be arbitrarily adjusted by such a correction value.

### Specific Embodiment

Next, a specific embodiment will be described in which the above-described control device is applied to temperature control of a substrate in a single-wafer film formation apparatus as the substrate processing apparatus.

### [Film Formation Apparatus]

FIG. 2 is a cross-sectional view illustrating an example of a film formation apparatus as a substrate processing apparatus to which a control device according to one embodiment is applied.

A film formation apparatus 1 forms a film on a substrate S by chemical vapor deposition (CVD) or atomic layer deposition (ALD) and includes a chamber 2. A stage 3 on which the substrate S is placed horizontally and heated is provided inside the chamber 2. In this example, one substrate S is placed on the stage 3, and the film formation apparatus 1 is configured as a single-wafer apparatus. The stage 3 functions as a holding mechanism for holding the substrate and as a heating mechanism for heating the substrate. A plurality of substrates S may be placed on the stage 3. For example, the film formation apparatus 1 may be a two-wafer or four-wafer apparatus in which two or four substrates S are placed on the stage 3.

The stage 3 includes a stage body, a heater 4 provided inside the stage body, and a heater power supply (not shown) that supplies power to the heater 4. The heater 4 and the heater power supply constitute a heater system. The stage 3 has an inner zone 3a and an outer zone 3b. The heater 4 is configured as a two-zone heater, including an inner heater 4a corresponding to the inner zone 3a and an outer heater 4b corresponding to the outer zone 3b. Alternatively, the stage 3 may have a single heater without zone division or a heater divided into three or more zones. A thermocouple 10, which is a temperature detector, is provided near the substrate S at the center of the stage 3, and temperature control is performed based on a detected value from the thermocouple 10, as described below. The temperature detector is not limited to the thermocouple, and a resistance temperature detector or a radiation thermometer may be used as the temperature detector.

An exhaust pipe 5 is connected to a bottom portion of the chamber 2, and an exhaust mechanism 6, which includes a pressure control valve and a vacuum pump for controlling pressure inside the chamber 2, is connected to the exhaust pipe 5. A transfer port 7 through which the substrate S is transferred is formed in a side wall of the chamber 2, and the transfer port 7 is opened and closed by a gate valve 8.

A shower head 9 is provided at an upper portion of the chamber 2 so as to face the stage 3. The interior of the shower head 9 includes a gas chamber 9a, and a plurality of gas discharge holes 9b at a bottom portion of the shower head 9.

A gas supply portion 11 is connected to the shower head 9 via a gas passage 12. The gas supply portion 11 supplies one or plural gases necessary for film formation. The gas supply portion 11 includes a valve for starting or stopping gas supply and a flow rate controller (both not shown) for controlling gas flow rate. The gases from the gas supply portion 11 reach the gas chamber 9a of the shower head 9 via the gas passage 12 and are discharged into the chamber 2 via the gas discharge holes 9b.

The gas supply portion 11 and the shower head 9 constitute a processing mechanism for processing the substrate S inside the chamber 2. The processing mechanism may also include a plasma generation mechanism for converting the gases supplied from the gas supply portion 11 into plasma.

The film formation apparatus 1 also includes a control system 20. The control system 20 controls each component of the film formation apparatus 1 based on a process recipe. The control system 20 includes a control device 30 of the present embodiment, which controls the temperature of the substrate S on the stage 3. The control system 20 may be configured as a single controller or may include a device controller, which is a higher-level controller having the process recipe, and a temperature controller, which is a lower-level controller.

### [Control Device]

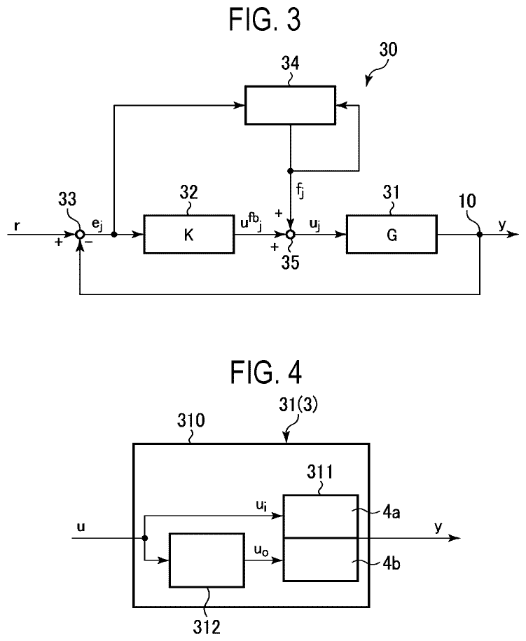

FIG. 3 is a control block diagram illustrating the control device according to the embodiment. The control device 30 controls a control target 31 and includes a feedback controller 32 and a correction value calculator 34.

In the present embodiment, the control target 31 is the stage 3 which includes a stage body 310, a two-zone heater system 311 for heating the stage body 310, and a power ratio setting portion 312, as shown in the block diagram in FIG. 4. The heater system 311 includes an inner heater 4a of an inner zone, an outer heater 4b of an outer zone, and power supplies (not shown) that supply power to the inner heater 4a and outer heater 4b, respectively. The power ratio setting portion 312 sets a power ratio of the inner heater and the outer heater. In this example, the power ratio setting portion 312 fixes the power ratio at a certain set value, and control input (power) u is distributed to the inner heater as power uᵢ and the outer heater as power uₒ. Since the thermocouple 10, which is a detector, corresponds only to the inner heater, the heater system 311 is a one-input, one-output system despite employing a two-zone heater. As described above, the control target 31 (stage 3) may have a single heater that is not divided into zones or may have a heater divided into three or more zones.

The feedback controller 32 outputs a control signal so that deviation (error) e, calculated by a subtractor 33, between a target value r and a detected value y from the thermocouple 10, which is a detector, is eliminated, thereby controlling the temperature of the control target 31 (stage 3). Thus, the temperature of the substrate S on the stage 3 is controlled. The target value r is set, for example, by a setter (not shown). A control method of the feedback controller 32 is not particularly limited. For example, feedback control using proportional integral derivative (PID) control, proportional integral (PI) control, or modern control theory can be used.

The correction value calculator 34 acquires a deviation (error) eⱼ in j-th substrate processing (where j is an integer of 1 or greater) and calculates a correction value fⱼ to be added to the control signal from the feedback controller 32 during (j+1)-th substrate processing, so that a deviation (error) eⱼ₊₁ in the (j+1)-th substrate processing becomes smaller than the deviation (error) eⱼ in the j-th substrate processing. In other words, the correction value calculator 34 calculates the correction value fⱼ so that a deviation (error) monotonically converges. The correction value fⱼ is added to the control signal in the adder 35.

The correction value calculator 34 is not particularly limited as long as the correction value calculator 34 has the functions described above, but an iterative learning control (ILC) circuit that performs ILC is a suitable example.

ILC refers to control that reduces an error to a target by repeatedly performing tracking control (trial) for a target trajectory of a control target.

ILC is an established technology. A control device using ILC is described, for example, in Japanese Patent Laid-Open Publication No. 2009-205641, and the description regarding ILC disclosed therein can also be applied to the present embodiment. However, the technology described in Japanese Patent Laid-Open Publication No. 2009-205641 applies ILC to a position control device, which pertains to a different field from the present embodiment, which relates to the control of a state quantity such as temperature or pressure in substrate processing, and does not suggest the present embodiment.

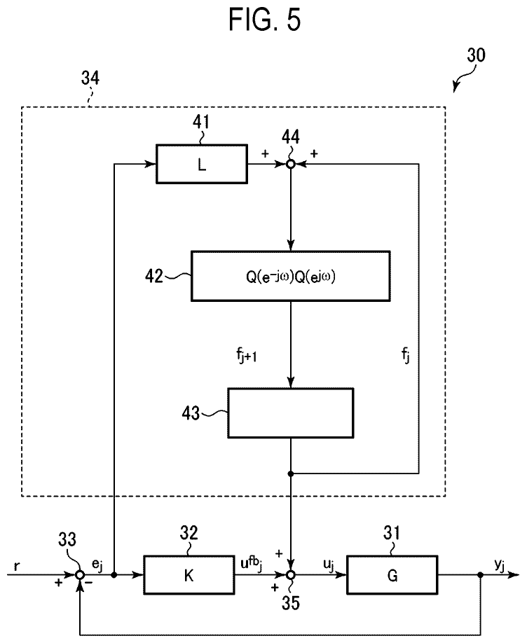

FIG. 5 is a control block diagram in a case in which the correction value calculator 34 of the control device 30 is an ILC circuit. The ILC circuit constituting the correction value calculator 34 includes an L filter 41, a Q filter 42, a memory 43, and an adder 44.

The L filter 41 is a learning filter. The Q filter 42 is a frequency cutoff filter having the function of blocking a specific frequency band. A deviation eⱼ in j-th substrate processing (where j is an integer of 1 or greater) is input to the L filter 41 as an error, and the output of the L filter 41 is input into the adder 44. The deviation eⱼ is time-series data. In addition, an ILC signal fⱼ corresponding to the j-th substrate processing from the ILC circuit is also input to the adder 44. The output from the adder 44 is input into the Q filter 42. The output from the Q filter 42 is stored in the memory 43 as a (j+1)-th ILC signal fⱼ₊₁. The ILC signal fⱼ₊₁ stored in the memory 43 is input to the adder 35 as a correction value fⱼ₊₁ that is added to a control signal u^{fb}ⱼ₊₁ from the feedback controller 32 during (j+1)-th substrate processing. The ILC signal (correction value) fⱼ₊₁ may be time-series data. Furthermore, if the convergence of the deviation (error) eⱼ can be guaranteed only by the L filter 41, the Q filter 42 may not be used.

In ILC, control precision can be raised by frequently updating an ILC signal every time substrate processing is performed. Settings for an ILC circuit (the L filter 41 etc.) can also be changed depending on substrate processing conditions. For example, the L filter can be designed as follows:

When the L filter 41 is defined as L(jω), the control target 31 as G(jω), the feedback controller 32 as K(jω), and a sensitivity function in a feedback control system as S(jω), then S(jω) can be expressed by Equation (1) below, and a deviation (error) eⱼ₊₁ in (j+1)-th substrate processing can be expressed by Equation (2) below.

$$S ( j ω ) = 1 / ( 1 + G ( j ω ) K ( j ω ) ) \qquad ( 1 )$$

$${e}_{j + 1} = ( 1 - G ( j ω ) S ( j ω ) L ( j ω ) ) ) {e}_{j} \qquad ( 2 )$$

In Equation (2), G(jω)S(jω) is a frequency response determined by the configuration of the feedback controller 32 and the control target 31.

Based on Equation (2), a condition under which the deviation (error) eⱼ monotonically converges (i.e., a condition under which eⱼ₊₁ is smaller than eⱼ) is that Equation (3) below is satisfied for all frequencies.

$$\vert ( 1 - G ( j ω ) S ( j ω ) L ( j ω ) ) \vert < 1 \qquad ( 3 )$$

In Equation (3), if Equation (4) below can be designed, then G(jω)S(jω)L(jω) becomes 1, and theoretically, the deviation (error) eⱼ₊₁ can be 0.

$${L ( j ω ) = G ( j ω ) S ( j ω ) )}^{- 1} \qquad ( 4 )$$

When a model of the control target and a model of the sensitivity function, obtained from estimated values, are denoted by giving hats (\hat{ }) to G(jω) and S(jω), respectively, L(jω) is expressed by Equation (5), and using this relationship, L(jω) (i.e., the L filter 41) can be designed.

$$- L ( j ω ) = {( {G}^{A} ( j ω ) {S}^{A} ( j ω ) )}^{- 1} \qquad ( 5 )$$

In this case, the following (a) or (b) can be used as a design method for L(jω).
(a) is a method for designing L(jω) from G(jω)S(jω) (with hats), which is directly obtained from closed-loop system identification. This method has the advantage of being easy to implement when the frequency response of a feedback controller is unknown. However, if the gain of the feedback controller changes, closed-loop system identification needs to be performed again.
(b) is a method for designing L(jω) from G(jω) (with a hat) and K(jω), which is the model of the feedback controller. K(jω) is obtained using Equation (6) below. This method makes it easy to redesign L(jω) because, if the gain of the feedback controller changes, only a transfer function of the feedback controller needs to be obtained and it is not necessary to perform closed-loop system identification again. Therefore, it is easy to redesign L(jω). As a result, (b) is a method which is easy to use when the frequency response of the feedback controller can be calculated.

$${S}^{A} ( j ω ) = \frac{1}{1 + {G}^{A} ( j ω ) K ( j ω )} \qquad ( 6 )$$

Next, an experiment will be described for designing L(jω) of the L filter 41 in ILC using the method of (a). In the following description, the design of the Q filter 42 will also be explained.

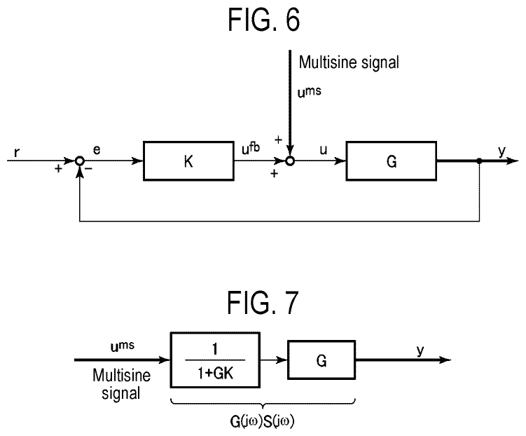

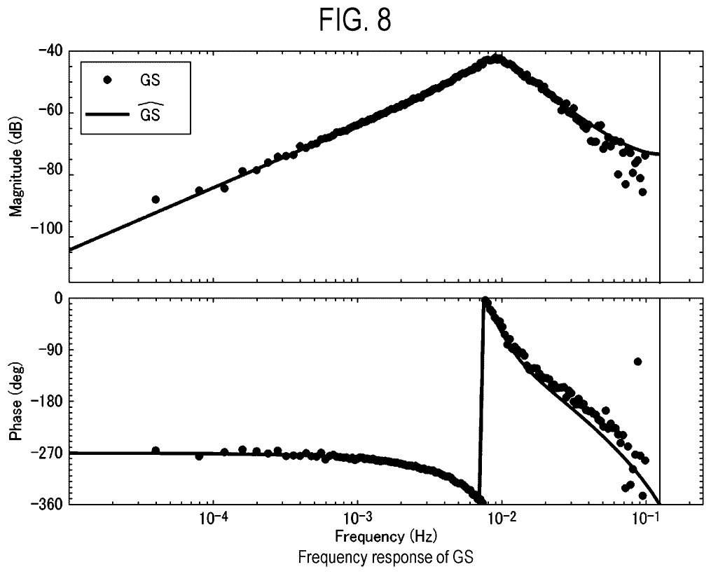

Closed-loop system identification was performed by applying a multisine signal as external input (time-series data) while applying feedback in a feedback control circuit having a circuit configuration shown in FIG. 6. The control circuit of FIG. 6 can be equivalently transformed into a control circuit shown in FIG. 7. The control circuit of FIG. 7 receives a multisine signal (time-series data) as input and outputs temperature (time-series data). The control circuit of FIG. 7 can directly acquire G(jω)S(jω) as a frequency response. FIG. 8 illustrates a frequency response in this case. In FIG. 8, gain and phase at each frequency are plotted. From these data, modeling of G(jω)S(jω) (hereinafter referred to as GS) was performed by fitting. GS (with a hat) modeled by fitting is shown in FIG. 8.

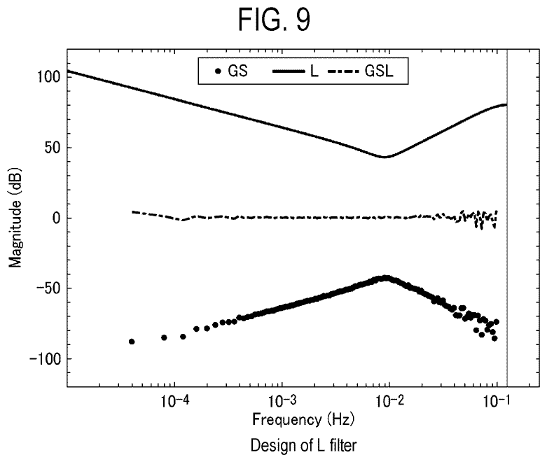

From the results of this modeling, Loc) (hereinafter referred to as L, as shown in FIG. 9) was determined as shown in FIG. 9 based on the relationship in Equation (4) above, and the L filter 41 was designed. FIG. 9 illustrates plots for GS and G(jω)S(jω)L(jω) (hereinafter referred to as GSL, as shown in FIG. 9), in addition to L.

However, with only L designed in this way, the value of |1−GSL| may become greater than 0 dB in a high-frequency range, and convergence of the deviation (error) eⱼ may not be guaranteed. For this reason, the Q filter 42, represented by Q(e^{-jω})Q(e^{jω}) (=|Q(jω)|² (hereinafter referred to as |Q|²)), is provided, and the Q filter is designed so that the convergence of the deviation (error) evaluated as |Q|²|1−GSL| satisfies Equation (7) below at all frequencies.

$${\vert Q \vert}^{2} \vert 1 - GSL \vert < 1 \qquad ( 7 )$$

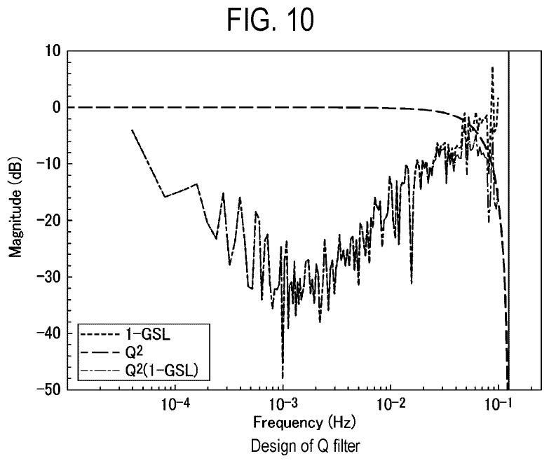

In the example shown in FIG. 10, while |1−GSL| is greater than 0 dB in a high-frequency range, |Q|²|1−GSL| can be made less than 0 dB or less in all frequency ranges by designing the Q filter 42 to satisfy Equation (7).

From the foregoing, it was confirmed that the design of L and Q, which guarantees the convergence of the deviation (error) eⱼ, can be performed using the frequency domain model. Additionally, if the convergence of the deviation (error) eⱼ can be guaranteed only by the design of the L filter 41 (the design of L(jω)), then, as mentioned above, the Q filter 42 may not be used.

When the control system 20 includes the higher-level device controller and the lower-level temperature controller, the feedback controller 32 of the control device 30 is included in the temperature controller but the correction value calculator 34 may be included in either the device controller or the temperature controller.

When the correction value calculator 34 is included in the device controller, since calculation from the correction value calculator 34 is performed by the device controller, this has the advantage of requiring minimal resources from the temperature controller. However, the disadvantage is that it takes time because a deviation (error) signal or a correction value signal needs to be transmitted.

On the other hand, when the correction value calculator 34 is included in the temperature controller, calculation from the correction value calculator 34 is performed by the temperature controller. This has the advantage of eliminating the need to transmit the correction value signal and, when testing the correction value calculator 34, few changes need to be made to the device controller. However, this has the disadvantage that the number of recipes or steps to which the correction value calculator 34 is applied increases, resulting in a larger amount of data stored in the temperature controller, or the correction value needs to be calculated without affecting a temperature control cycle.

### [Processing Operation]

Next, the processing operation of the film formation apparatus 1, configured as described above, will be described.

In the film formation apparatus 1, the substrate S is loaded into the chamber 2 and is placed on the stage 3. The inside of the chamber 2 is brought to a predetermined vacuum pressure, and the stage 3 is set to a predetermined temperature. Gas for film formation is then supplied into the chamber 2 at a predetermined flow rate via the shower head 9 from the gas supply portion 11, thereby performing film formation processing. During this film formation processing, based on a process recipe stored in the control system 20, the pressure inside the chamber 2 is controlled by the pressure control valve, the gas flow rate is controlled by the flow rate controller, and the temperature of the stage 3 constituting the control target 31 is controlled by the control device 30.

Temperature control by the control device 30 is performed based on feedback control by the feedback controller 32 and a correction value calculated by the correction value calculator 34. The correction value calculator 34 acquires a deviation (error) eⱼ in j-th substrate processing (where j is an integer of 1 or greater) and calculates a correction value fⱼ₊₁ to be added to a control signal from the feedback controller 32 during (j+1)-th substrate processing, so that a deviation (error) eⱼ₊₁ in the (j+1)-th substrate processing becomes smaller than the deviation (error) eⱼ.

Specifically, a case in which an ILC circuit is used as the correction value calculator 34 will now be described.

The deviation eⱼ in the j-th substrate processing (where j is an integer of 1 or greater) is input to the L filter 41, and the output of the L filter 41 is input to the adder 44. In addition, a j-th ILC signal (correction value) fⱼ of the ILC circuit is also input to the adder 44. The output of the adder 44 is input to the Q filter 42. The output of the Q filter 42 is stored in the memory 43 as a (j+1)-th ILC signal fⱼ₊₁. The ILC signal fⱼ₊₁ stored in the memory 43 is added to a control signal u^{fb}ⱼ₊₁ from the feedback controller 32 as the correction value fⱼ₊₁ in the (j+1)-th substrate processing. During the first substrate processing, temperature control is performed only by feedback control.

While the feedback controller 32 can always perform calculation continuously, the correction value calculator 34 cannot calculate the correction value fⱼ₊₁ during the j-th substrate processing because the correction value calculator 34 acquires the deviation (error) eⱼ during the j-th substrate processing and, at the same time, calculates the correction value fⱼ₊₁ (i.e., the ILC signal fⱼ₊₁) used in the next substrate processing.

Therefore, the calculation of the correction value by the correction value calculator 34 needs to be performed during a period during which substrate processing is not being executed. For example, the calculation of the correction value by the correction value calculator 34 is performed at a timing when substrate processing is completed or when an arbitrary step is completed.

Specifically, when continuously performing a plurality of substrates processing operations in the substrate processing apparatus, the following processing operations are performed. First, the correction value calculator 34 calculates the correction value fⱼ₊₁ while continuing to perform feedback control by the feedback controller 32 in a period during which substrate processing is not performed after the j-th substrate processing (where j is an integer of 1 or greater). Then, during the next (j+1)-th substrate processing, the correction value fⱼ₊₁ is added to the control signal of the feedback controller 32 to perform temperature control of the stage 3, which is a state quantity.

Additionally, a timing of starting the adding the correction value to the control signal of feedback control may be set at the start of the process recipe or at a timing specified in the process recipe.

In substrate processing, there are cases in which processing based on a plurality of process recipes is performed in a single chamber. If the process recipes are different, a timing when the substrate is loaded into the chamber, gas flow rate, pressure, and the like may change, which can make reproducibility of disturbances in stage temperature impossible. While ILC is highly effective for disturbances with high reproducibility, ILC is vulnerable in a situation in which significantly different disturbances occur. Therefore, it is effective to associate a correction value (ILC signal) with each process recipe, store the correction value in the memory of the control system 20, and retrieve the correction value associated with the process recipe being executed. Furthermore, this is not limited to a one-to-one correspondence between a correction value and a process recipe, and the correction value can also be associated with a plurality of process recipes. For example, in heating the stage to a specific temperature (e.g., 200 to 300 degrees C.), if there is a plurality of process recipes in which the subsequent process conditions are different, a correction value for a heating portion of such a specific temperature can be used in common across these plural process recipes.

Additionally, controllability of the control target 31 (stage 3) varies depending on the chamber 2. Even within the same chamber, controllability differs depending on the state of the control target 31 (stage 3) (e.g., the number of substrates on the stage 3 (e.g., 1 substrate, 2 substrates, 4 substrates, etc.)). For this reason, a correction value may be associated with each combination of a process recipe and a chamber or each combination of a process recipe and a control target 31 (the stage 3). The associated correction values are stored in the memory and retrieved as appropriate.

Furthermore, the state of the chamber may change while processing a plurality of substrates. In such cases, a correction value may be used separately for each substrate, for example, for each of the first to 25th substrates in a single lot.

Instead of the process recipe, common ILC information can be associated with a substrate placement step.

As described above, in the specific embodiment, the control device 30 is configured to include the correction value calculator 34 in addition to the feedback controller 32. The correction value calculator 34 acquires a deviation (error) eⱼ in j-th substrate processing and calculates a correction value fⱼ₊₁ to be added to a control signal u^{fb}ⱼ₊₁ from the feedback controller 32 during (j+1)-th substrate processing, so that a deviation (error) eⱼ₊₁ in the (j+1)-th substrate processing becomes smaller than the deviation (error) eⱼ. The correction value fⱼ₊₁ is added to the control signal u^{fb}ⱼ₊₁ from the feedback controller 32 during the (j+1)-th substrate processing. That is, the correction value fⱼ₊₁ is used as a feedforward signal. As a result, by suppressing a temperature fluctuation of the stage 3 caused by a disturbance and the like, the temperature can stabilize within the desired range in a shorter time. In addition, by using such a correction value, a temperature behavior (temperature waveform) of the stage 3 constituting the control target 31 can be adjusted to a desired temperature behavior (temperature waveform).

This point will now be described in detail.

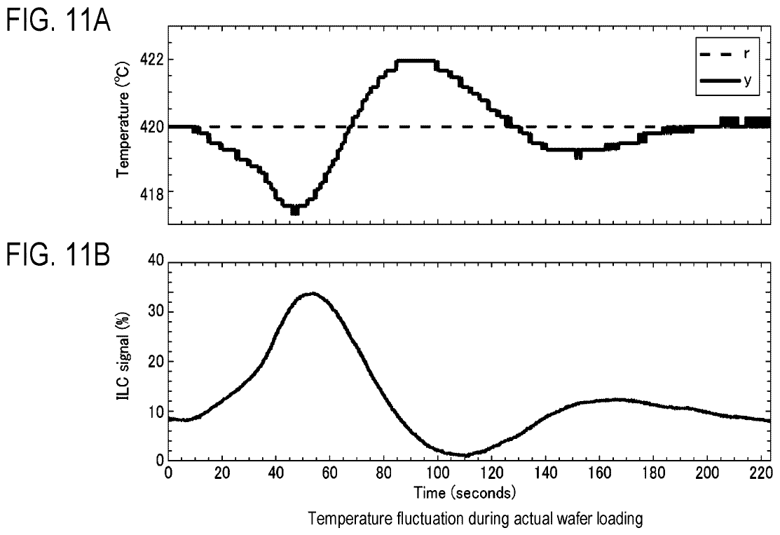

In the related art, temperature control of the stage, which is the control target, has been generally performed using feedback control alone. However, since feedback control controls the control target based on an actually detected value, delay occurs in control. As a result, when the deviation (error) e between the detected value y and the target value r increases due to a disturbance such as substrate temperature, overshoot and the like occur, resulting in an increase in the fluctuation of the stage temperature. Thereby, it takes time for temperature to stabilize at the target value, reducing throughput. For example, when the substrate is placed on the stage controlled to a processing temperature, the stage temperature drops, as shown in FIG. 11A. Thereby, as shown in FIG. 111B, the feedback controller attempts to restore temperature and thus control input increases. In contrast, temperature increases excessively and it takes a long time to converge to a target temperature range. Furthermore, if the fluctuation of the stage temperature is large, energy applied to the substrate can easily vary between devices, making it likely for a machine difference to occur in a process result. When a set temperature of the stage is reduced, a controllable range against a disturbance only by feedback control becomes limited, causing a period during which the control input is zero, and controllability deteriorates.

In addition, the substrate has various states. For example, when the substrate is a wafer, there are a bare wafer, a patterned wafer, or a wafer with different film thicknesses for formed films. When the state of the substrate differs, the behavior of stage temperature may change, thereby affecting controllability of the stage temperature. As processing is repeatedly performed, a state within a chamber may change due to, for example, film accumulation within the chamber or component consumption within the chamber, thereby affecting controllability of the stage temperature. In addition, when substrate transfer and loading conditions of a recipe differ, or between different chambers or different stages, the controllability of the stage temperature changes. These differences in controllability act as disturbances that affect the process result, and such differences in controllability cannot be handled by feedback control alone.

In this regard, the correction value calculator 34 calculates a correction value so that a deviation in (j+1)-th substrate processing is smaller than that in j-th substrate processing, and by adding this correction value to a control signal from the feedback controller 32, the fluctuation of the stage temperature caused by such disturbances can be suppressed, thereby resolving the problems.

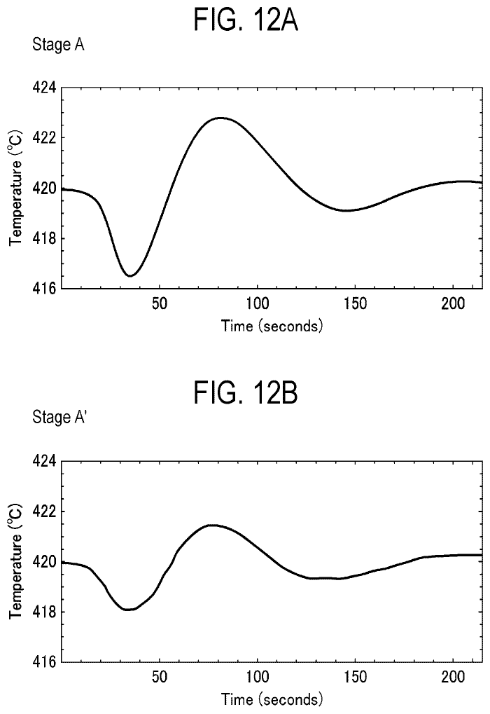

There is also a demand to adjust a temperature behavior (control waveform) of the stage 3, which is a control target, to a desired temperature behavior. In such a case, a target value is set as time-series data so that the stage achieves the desired temperature behavior. Further, as described above, by adding the correction value calculated by the correction value calculator 34 to the control signal of the feedback controller 32, the temperature of the stage can be made to follow the target value, which is the desired temperature behavior. For example, when a new stage A′ is developed as an improved version of an existing stage A, the control waveform (temperature behavior) of the stage A′ undergoing feedback control may differ from the control waveform (temperature behavior) of the stage A. In such a case, there is a demand to match the temperature behavior of the stage A′ to the temperature behavior of the stage A. Specifically, if the temperature behavior of the stage A is as shown in FIG. 12A and the temperature behavior of the stage A′ is as shown in FIG. 12B, the temperature behavior of the stage A′ is intended to be matched to the temperature behavior as shown in FIG. 12A. In this case, by setting the temperature behavior of the stage A as a target temperature for the stage A′ and adding the correction value calculated by the correction value calculator 34 to the control signal of the feedback controller 32 as described above, it is possible to match the temperature behavior of the stage A′ to the temperature behavior of the stage A, which is the target temperature.

### EXPERIMENTAL EXAMPLE

Next, an experimental example will be described.

### Experimental Example 1

Here, the effect will be described in the case in which, in controlling a wafer, which is the substrate, on the stage at 420 degrees C., an ILC signal (correction value) calculated using the ILC circuit as the correction value calculator is added to a control signal of the feedback controller.

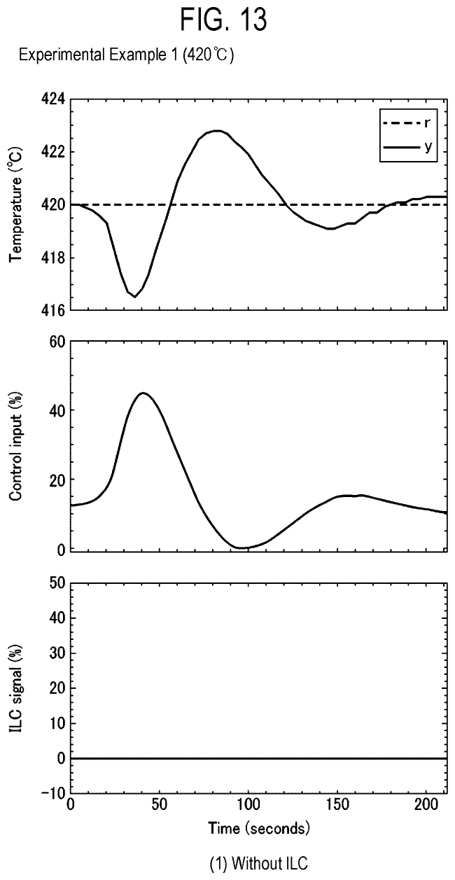

In the first experiment, the temperature of the stage was controlled using feedback control alone without employing the ILC circuit. The results are shown in FIG. 13. As shown in the figure, the temperature of the stage dropped sharply due to the placement of the wafer, and accordingly, control input increased rapidly, resulting in an increase in the fluctuation of the stage temperature.

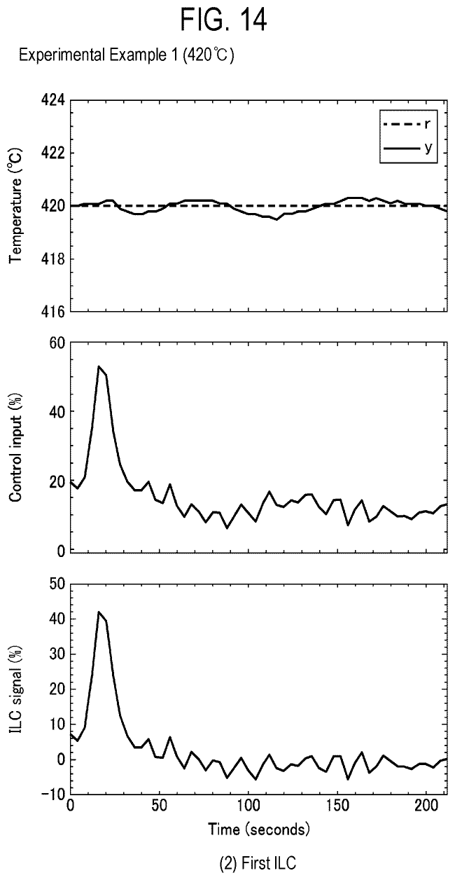

Next, the first ILC experiment was conducted in which the ILC signal was generated by the ILC circuit using the temperature of the stage obtained in the experiment without employing the ILC circuit, and the ILC signal was applied as the correction value to the control signal of the feedback controller. The results are shown in FIG. 14. As shown in FIG. 14, by applying the ILC signal, the control input was adjusted and the fluctuation of the stage temperature was sufficiently suppressed, resulting in an extremely small fluctuation of within 0.6 degrees C.

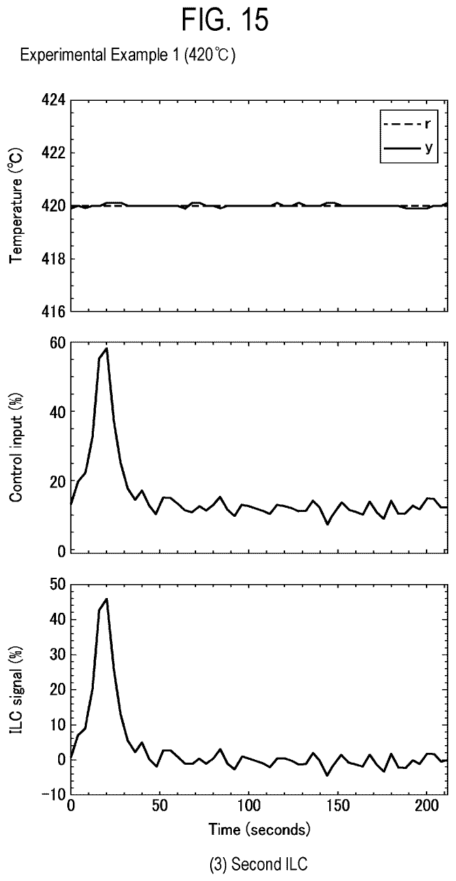

Next, the second ILC experiment was conducted in which the ILC signal was generated by the ILC circuit using the temperature of the stage obtained in the first ILC experiment, and the ILC signal was applied as the correction value to the control signal of the feedback controller. The results are shown in FIG. 15. As shown in FIG. 15, by applying the second ILC signal, the suppressed state of the fluctuation of the stage temperature was maintained, and the fluctuation of the stage temperature was further reduced to within 0.4 degrees C.

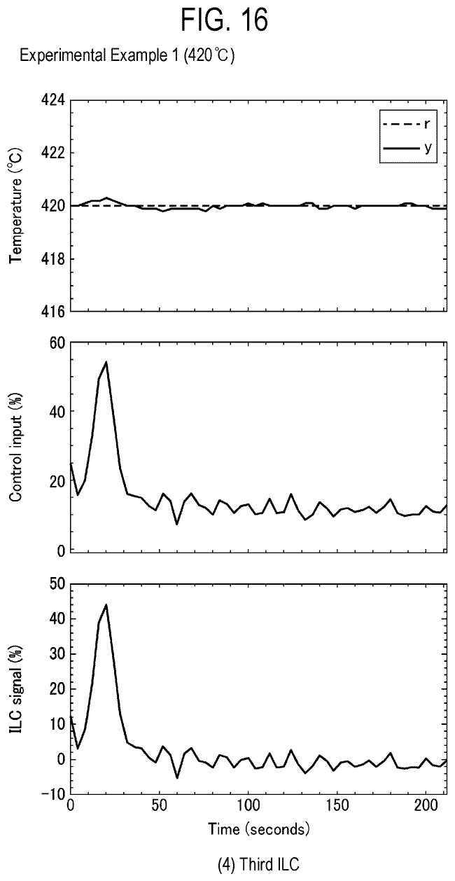

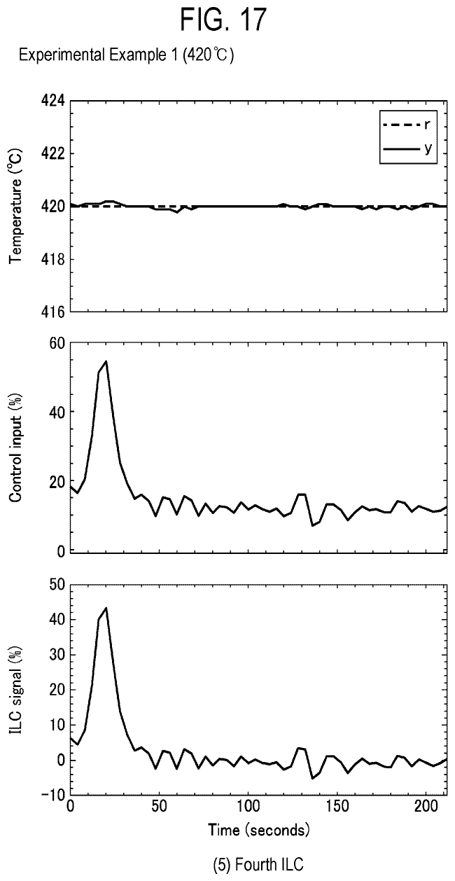

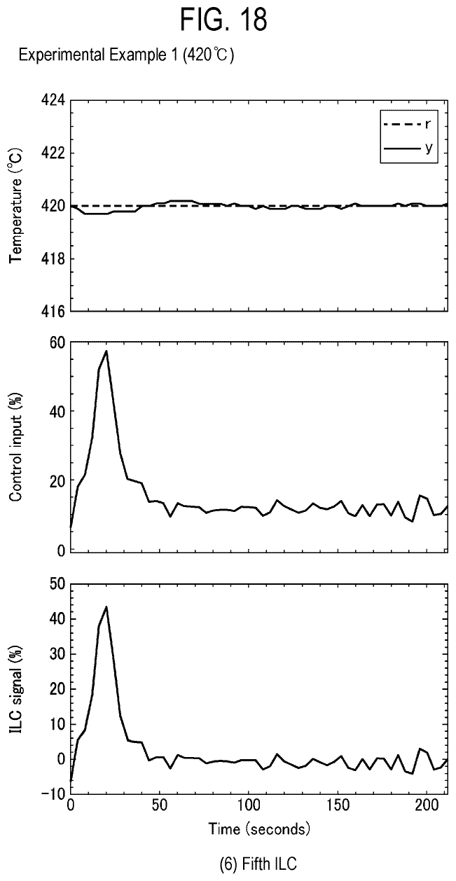

Similarly, the third to fifth ILC experiments were conducted in which the ILC signal was generated using the temperature of the stage obtained in the previous experiment, and the ILC signal was applied as the correction value to the control signal of the feedback controller. The results are shown in FIGS. 16 to 18, respectively. As shown in FIGS. 16 to 18, even in the ILC experiments after the third ILC experiment, the suppressed state of the fluctuation of the stage temperature was maintained and the temperature fluctuation in the third ILC experiment was within 0.5 degrees C., and the temperature fluctuations in the fourth and fifth ILC experiments were within 0.4 degrees C.

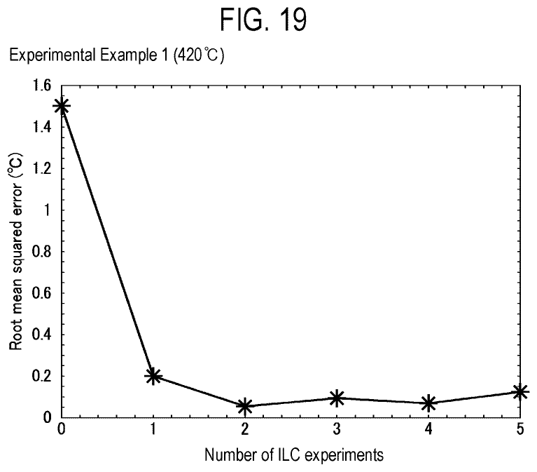

FIG. 19 is a diagram illustrating a relationship between the number of ILC experiments and a root mean squared error (RMSE) representing the fluctuation of the stage temperature in Experimental Example 1. As shown in FIG. 19, it was confirmed that the fluctuation of the stage temperature sufficiently converged in the first ILC experiment and that the state of sufficient convergence of the temperature fluctuation was maintained in the subsequent second to fifth ILC experiments as well.

### Experimental Example 2

Here, the effect will be described in the case in which, in controlling the wafer, which is the substrate, on the stage at 250 degrees C., an ILC signal (correction value) calculated using the ILC circuit designed at 420 degrees C., as in Experimental Example 1, was applied.

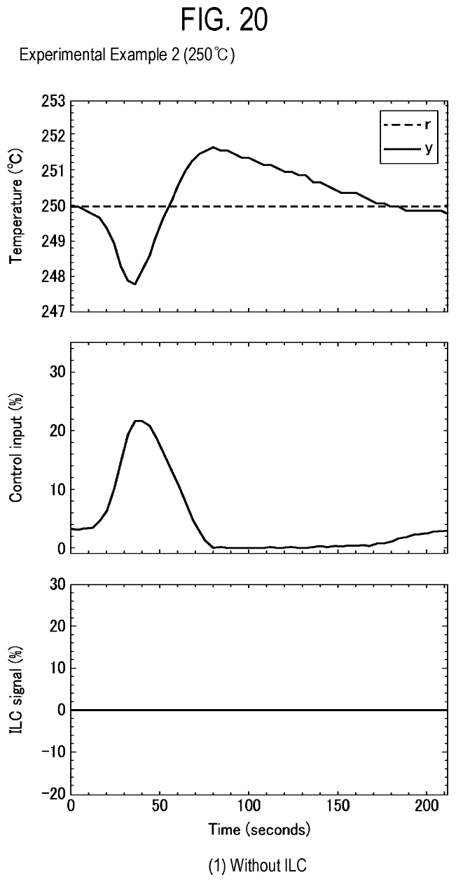

In the first experiment, the temperature of the stage was controlled using feedback control alone without employing the ILC circuit. The results are shown in FIG. 20. As shown in FIG. 20, the temperature of the stage dropped sharply due to the placement of the wafer, and accordingly, control input increased rapidly. Then, due to the overshoot of the temperature of the stage accompanying the increase in control input, the control input became fixed at 0%, resulting in an uncontrolled state in which the fluctuation of the stage temperature becomes large.

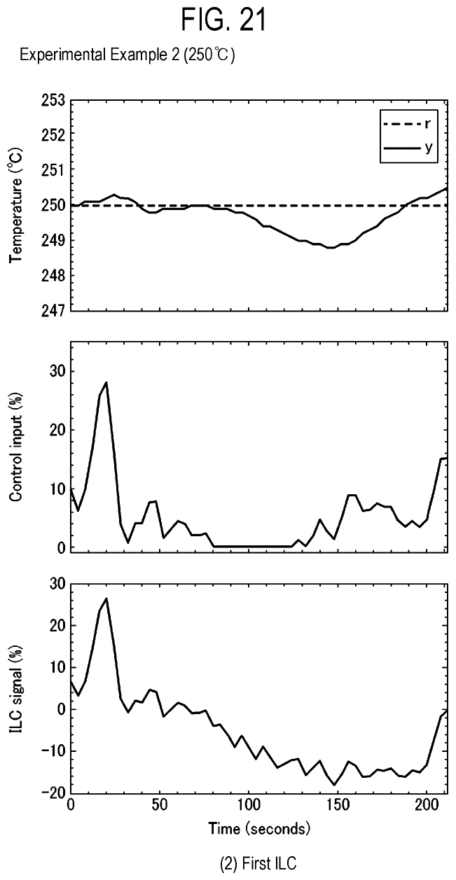

Next, the first ILC experiment was conducted in which the ILC signal was generated by the ILC circuit using the temperature of the stage obtained in the experiment without employing the ILC circuit, and the ILC signal was applied as the correction value to the control signal of the feedback controller. The results are shown in FIG. 21. As shown in the FIG. 21, by applying the ILC signal, the control input was adjusted and the fluctuation of the stage temperature was suppressed to a certain extent. However, it was confirmed that, due to the ILC signal becoming significantly negative, the temperature of the stage tended to decrease in the latter part of the experiment, and the temperature fluctuation was slightly larger.

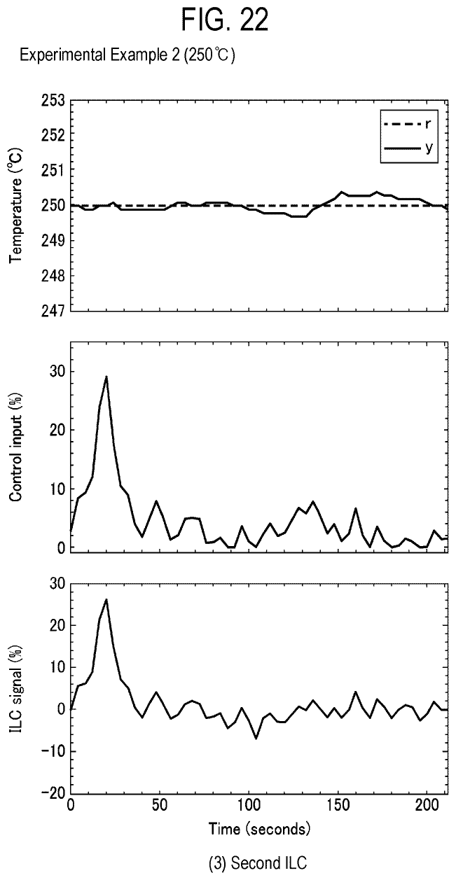

Next, the second ILC experiment was conducted in which the ILC signal was generated by the ILC circuit using the temperature of the stage obtained in the first ILC experiment, and the ILC signal was applied as the correction value to the control signal of the feedback controller. The results are shown in FIG. 22. As shown in FIG. 22, by applying the second ILC signal, the fluctuation of the stage temperature was sufficiently suppressed, resulting in an extremely small temperature fluctuation of within 0.4 degrees C.

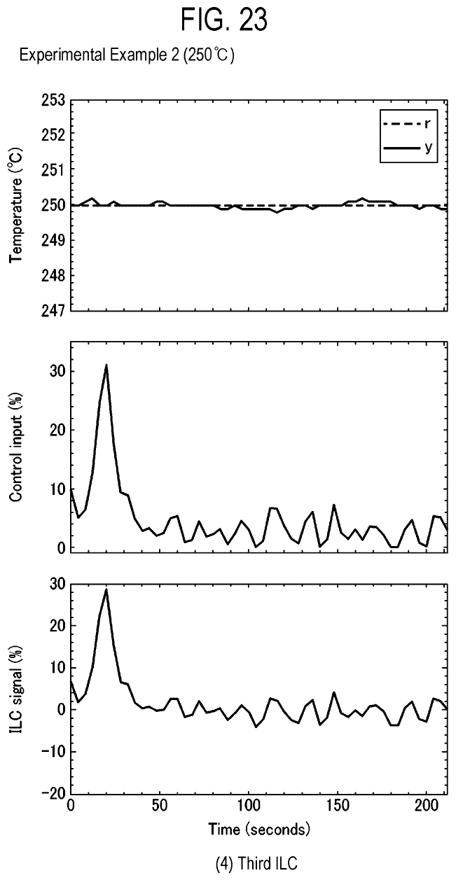

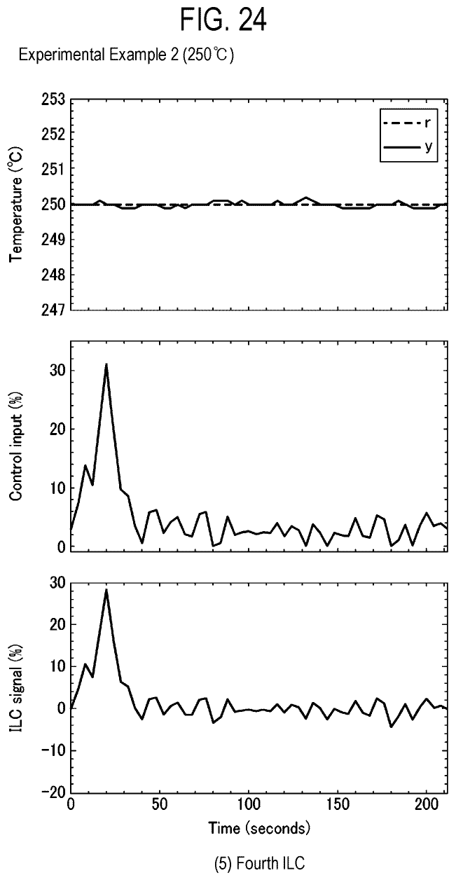

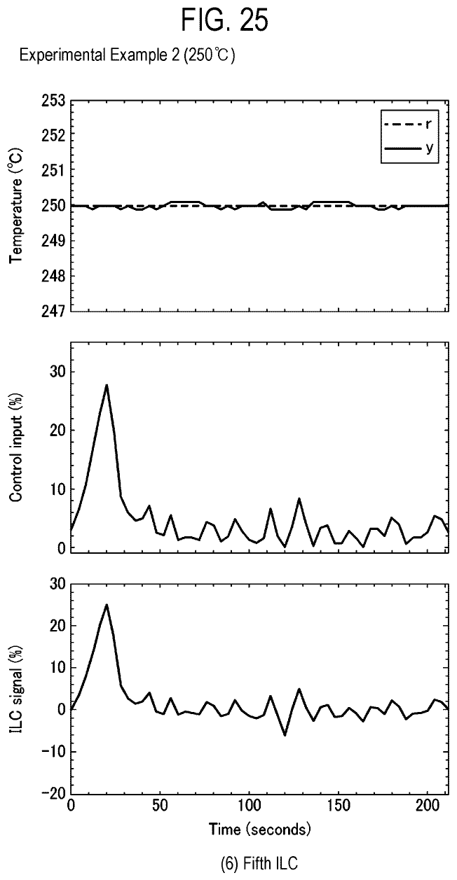

Similarly, the third to fifth ILC experiments were conducted in which the ILC signal was generated using the temperature of the stage obtained in the previous experiment, and the ILC signal was applied as the correction value to the control signal of the feedback controller. The results are shown in FIGS. 23 to 25, respectively. As shown in FIGS. 23 to 25, even in the ILC experiments after the third ILC experiment, the suppressed state of the fluctuation of the stage temperature was maintained and the temperature fluctuations were within 0.2 degrees C.

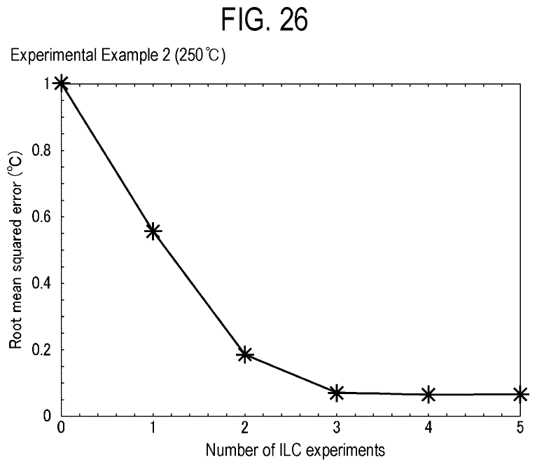

FIG. 26 is a diagram illustrating a relationship between the number of ILC experiments and an RMSE representing the fluctuation of the stage temperature in Experimental Example 2. As shown in the figure, although the fluctuation of the stage temperature decreased in the first ILC experiment, the fluctuation remained slightly large. However, it was confirmed that the temperature fluctuation sufficiently converged in the second ILC experiment and that the state of sufficient convergence of the temperature fluctuation was maintained in the subsequent third to fifth ILC experiments as well.

### OTHER APPLICATIONS

While the embodiment has been described hereinabove, it should be noted that the embodiment disclosed herein is exemplary in all respects and is not restrictive. The above-described embodiment may be omitted, replaced, and/or modified in various forms without departing from the scope and spirit of the appended claims.

For example, in the above-described embodiment, an example has been shown in which the temperature fluctuations relative to the target temperature converge. However, the present disclosure is also applicable to cases in which fluctuations during temperature rise or temperature fall converge until temperature reaches the target temperature.

In the above-described embodiment, the case in which a controlled state quantity is temperature has been described. However, if the state quantity is a state quantity during substrate processing in the substrate processing apparatus, the state quantity is not limited to temperature and may be another state quantity such as pressure or gas flow rate.

In the above-described embodiment, a description has been given of the substrate processing apparatus in which a substrate is placed on a stage and processing is performed on the substrate while controlling the temperature of the stage using a one-input one-output system. However, the present disclosure can also be applied to a stage having a plurality of zone-divided heaters to control the heaters of the respective zones. Furthermore, in the above-described embodiment, an example in which substrates are processed one by one has been shown, the present disclosure is not limited thereto and may also be applied to a batch-type processing apparatus in which a plurality of substrates is stacked and arranged inside a processing chamber for substrate processing. While the substrate processing has been described with an example of supplying gas to the substrate to perform CVD or ALD film formation, the present disclosure is not limited thereto and may also be applied to physical vapor deposition (PVD) film formation involving sputtering a target. Moreover, the present disclosure is not limited to the film formation processing and may also be applied to other substrate processing such as etching, oxidation, and diffusion.

In addition, in the above-described embodiment, an example has been shown in which the correction value calculator based on ILC is applied to feedback control. However, the present disclosure may apply the correction value calculator to two-degree-of-freedom control, for example, control combining feedback control and feedforward control.

In addition, in the above-described embodiment, an example in which ILC is used as the correction value calculator has been described. However, the present disclosure is not limited thereto and numerical control based on AI or the like may be used.

According to the present disclosure in some embodiments, there are provided a control device, a substrate processing apparatus, and a substrate processing method capable of achieving controllability, which cannot be obtained using feedback control in the related art, in controlling a state quantity in substrate processing by the substrate processing apparatus.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A control device for controlling a state quantity in a substrate processing apparatus performing processing on a substrate, the control device comprising:
a feedback controller configured to apply a control signal to a control target, based on a deviation between a target value of the state quantity and a detected value from a detector; and
a correction value calculator configured to acquire a deviation eⱼ between the target value and the detected value in j-th substrate processing (where j is an integer of 1 or greater) and to calculate a correction value to be added to the control signal from the feedback controller during (j+1)-th substrate processing, so that a deviation eⱼ₊₁ between the target value and the detected value in the (j+1)-th substrate processing becomes smaller than the deviation eⱼ.

2. The control device of claim 1, wherein the correction value calculator is an iterative learning control (ILC) circuit performing ILC and outputs an ILC signal as the correction value.

3. The control device of claim 2, wherein the ILC circuit comprises:
a learning filter to which the deviation is input;
an adder configured to add an ILC signal fⱼ, which is the correction value during the j-th substrate processing to an output of the learning filter when the deviation eⱼ is input to the learning filter as the deviation; and
a memory configured to store output of the adder as an ILC signal fⱼ₊₁, which is the correction value in the (j+1)-th substrate processing.

4. The control device of claim 3, wherein the ILC circuit further includes a frequency cutoff filter having a function of blocking a specific frequency band of the output of the adder.

5. The control device of claim 4, wherein, when the learning filter is defined as L(jω), a frequency response determined in a configuration of the feedback controller and the control target is defined as G(jω)S(jω), and the frequency cutoff filter is defined as |Q(jω)|², then

|Q(jω)|²|1-G(jω)S(jω)L(jω)|<1 is satisfied.

6. The control device of claim 5, wherein the substrate processing apparatus includes, as the control target, a stage on which the substrate is placed and heated inside a chamber and controls a temperature of the stage as the state quantity.

7. The control device of claim 6, wherein the control device is configured to suppress a fluctuation of the temperature of the stage caused by a disturbance by adding the correction value calculated by the correction value calculator to the control signal of the feedback controller.

8. The control device of claim 7, wherein the disturbance is a difference between the temperature of the stage and the temperature of the substrate before the substrate is placed on the stage, a difference in a state of the substrate, or a change in a state within the chamber.

9. The control device of claim 2, wherein the substrate processing apparatus has a plurality of process recipes for controlling the processing on the substrate, and
wherein in the substrate processing apparatus, the ILC signal of the ILC circuit associated with each of the plurality of process recipes is stored as the correction value, and the correction value associated with an executed process recipe is retrieved.

10. The control device of claim 1, wherein the state quantity is temperature, pressure, or gas flow rate.

11. The control device of claim 1, wherein the substrate processing apparatus includes, as the control target, a stage on which the substrate is placed and heated inside a chamber and controls a temperature of the stage as the state quantity.

12. The control device of claim 11, wherein the control device is configured to set the target value as time-series data so that the stage achieves a desired temperature behavior, and configured to allow the temperature of the stage to follow the target value by adding the correction value calculated by the correction value calculator to the control signal of the feedback controller.

13. A substrate processing apparatus, comprising:
a chamber;
a substrate holding mechanism configured to hold a substrate inside the chamber;
a processing mechanism configured to perform processing on the substrate inside the chamber; and
a control system including a control device configured to control a state quantity during the processing,
wherein the control device further comprises:
a feedback controller configured to apply a control signal to a control target, based on a deviation between a target value of the state quantity and a detected value from a detector; and
a correction value calculator configured to acquire a deviation eⱼ between the target value and the detected value in j-th substrate processing (where j is an integer of 1 or greater) and to calculate a correction value to be added to the control signal from the feedback controller during (j+1)-th substrate processing, so that a deviation eⱼ₊₁ between the target value and the detected value in the (j+1)-th substrate processing becomes smaller than the deviation eⱼ.

14. The substrate processing apparatus of claim 13, wherein the correction value calculator of the control device is an iterative learning control (ILC) circuit performing ILC and outputs an ILC signal as the correction value.

15. The substrate processing apparatus of claim 14, wherein the control system is configured to store a plurality of process recipes for controlling the processing on the substrate and the ILC signal of the ILC circuit associated with each of the plurality of process recipes as the correction value, and configured to retrieve the correction value associated with an executed process recipe.

16. The substrate processing apparatus of claim 15, wherein the correction value is common to the plurality of process recipes.

17. The substrate processing apparatus of claim 13, wherein a stage on which the substrate is placed is provided as the substrate holding mechanism,
wherein the stage includes a heater and functions as the control target, and
wherein the control device controls a temperature of the stage as the state quantity.

18. The substrate processing apparatus of claim 17, wherein the control system includes a higher-level device controller configured to control the substrate processing apparatus based on a process recipe and a temperature controller configured to perform temperature control and including the feedback controller, and
wherein the correction value calculator is included in the device controller.

19. The substrate processing apparatus of claim 17, wherein the control system includes a higher-level device controller configured to control the substrate processing apparatus based on a processing recipe and a temperature controller configured to perform temperature control and including the feedback controller, and
wherein the correction value calculator is included in the temperature controller.

20. A substrate processing method of continuously processing a plurality of substrates in a substrate processing apparatus,
wherein the substrate processing apparatus includes:
a chamber;
a substrate holding mechanism configured to hold a substrate inside the chamber;
a processing mechanism configured to perform processing on the substrate inside the chamber; and
a control device configured to control a state quantity during the processing,
wherein the control device includes:
a feedback controller configured to apply a control signal to a control target, based on a deviation between a target value of the state quantity and a detected value from a detector; and
a correction value calculator configured to acquire a deviation eⱼ between the target value and the detected value in j-th substrate processing (where j is an integer of 1 or greater) and to calculate a correction value to be added to the control signal from the feedback controller during (j+1)-th substrate processing, so that a deviation eⱼ₊₁ between the target value and the detected value in the (j+1)-th substrate processing becomes smaller than the deviation eⱼ,
wherein the substrate processing method comprising:
calculating a correction value fⱼ₊₁ by the correction value calculator while continuing to perform control by the feedback controller in a period during which the processing is not performed on the substrate after the j-th substrate processing; and
upon starting the next (j+1)-th substrate processing, adding the correction value fⱼ₊₁ to the control signal of the feedback controller to perform control.
